(19) United States
(12) Patent Application Publication
(10) Pub. No.: US 2007/0147536 A1
(43) Pub. Date: Jun. 28, 2007

(54) Wireless communication device employing interference-sensitive mode selection and associated methods

(76) Inventors: Ezer Melzer, Tel-Aviv (IL); Daniel Yellin, Ra'anana (IL)

Correspondence Address: INTEL CORPORATION;C/O INTELLEVATE, LLC, P.O. BOX 52050, MINNEAPOLIS, MN, 55402, US

(21) Appl. No.: 11/319,298

(22) Filed: Dec. 27, 2005

(51) Int. Cl. H04L 1/02; H03D 1/00

(52) U.S. Cl. 375/267; 375/341

(57) ABSTRACT

Embodiments of a wireless communication system employing interference-sensitive mode selection and associated methods are generally introduced.

### TECHNICAL FIELD

Embodiments of the invention are generally directed to communication systems and, more particularly, to wireless communication devices that employ interference-sensitive mode selection and associated methods, protocols and/or signaling interface(s).

### BACKGROUND

The use of multiple signaling paths, e.g., through the use of multiple input multiple output (MIMO) technology can significantly increase the effective range and/or throughput of a wireless communication channel. Despite the significant advantages gained from the introduction of MIMO technology into a communications device, implementation issues persist which have heretofore limited the widespread adoption of such technologies.

An example of just such an implementation issue centers around the management of when and how to implement MIMO technology within a communication system. One of the elements currently being debated is the use of the remote station (STA) (or, mobile device, user equipment (UE), and the like) to report on whether it should be served by a true multi-stream MIMO transmission (that roughly doubles or quadruples the data rate), or by a single-stream transmission (e.g. using space-time coding that may only serve to improve the diversity order, and consequently increases the data rate only moderately). More specifically, the debate has centered on the decision criterion that should be employed in making the decision of what mode of operation the remote station should select in a given set of channel conditions.

Some recent proposals have posed that this selection between the multi-stream or single-stream MIMO modes of operation be based, either directly or indirectly, on a “rank” of the MIMO channel as measured by the remote station. While the use of a MIMO channel rank may be an excellent decision criterion when the underlying channel noise is spatially (and temporally) s white, such is not always the case in the field. Indeed, in a typical cellular system deployment, the “noise term” is composed mainly of interference from other cells and is, in this regard, often spatially (and temporally) colored. Thus, in practical implementations of wireless communication systems, establishing decision criterion based only on channel statistics will lead to poor performance.

### BRIEF DESCRIPTION OF THE DRAWINGS

Embodiments of the present invention are illustrated by way of example, and not by way of limitation, in the figures of the accompanying drawings in which like reference numerals refer to similar elements and in which:

FIG. 1 is a block diagram of an example communication system within which embodiments of the invention may be practiced;

FIG. 2 is a flow chart of an example method of supporting interference-sensitive mode selection within a receiver, according to one embodiment;

FIG. 3 is a flow chart of an example method of supporting interference-sensivit mode selection within a transmitter, according to one embodiment;

FIG. 4 is a graphical representation of the performance improvements achieved using the interference-sensitive mode selection techniques as compared against conventional mode selection techniques; and

FIG. 5 is a block diagram of an example element of manufacture including content which, when executed by an accessing machine, causes the machine to implement one or more aspects of interference-sensitive mode selection.

### DETAILED DESCRIPTION

Embodiments of a wireless communication device(s) employing interference-senstive mode selection and associated methods, protocols and/or signaling interface(s) are generally presented.

According to one embodiment, an improved multiple input, multiple output (MIMO) communication system is introduced that employs an interference-sensitive mode selection. According to one aspect, a receiver is introduced with an estimator that estimates the channel and the spatial covariance and the noise plus interference. It will be appreciated that the estimation of a noise plus interference spatiotemporal covariance matrix is not trivial, especially in high-SNR regions (where MIMO is most effective), as estimating the noise statistics when the noise term is significantly smaller than the signal is quite difficult. As discussed more fully below, the novel estimator disclosed herein may well employ one or more of several low complexity approaches for estimating such parameters. According to one embodiment, the novel estimator is a maximum-likelihood estimator that utilizes the turbo decoder a-posteriori log-likelihood ratios to smooth-out the effects of the unknown transmitted symbols, thus providing the log-likelihood sequence required for the covariance estimation.

According to one embodiment, the receiver includes a feedback mechanism through which certain data, based on the output of the estimator, is transferred from the receiver to one or more remote transmitter(s).

According to another aspect, a transmitter may include a mode controller, responsive to feedback from one or more receiver(s), to dynamically reconfigure itself to improve (i.e., substantially optimize) the forward channel for subsequent transmissions, effectively adapting the transmission parameters according to the channel's condition as well as to the interference from which the receiver suffers.

Reference throughout this specification to “one embodiment” or “an embodiment” means that a particular feature, structure or characteristic described in connection with the embodiment is included in at least one embodiment of the present invention. Thus, appearances of the phrases “in one embodiment” or “in an embodiment” in various places throughout this specification are not necessarily all referring to the same embodiment. Furthermore, the particular features, structures or characteristics may be combined in any suitable manner in one or more embodiments.

According to some embodiments, the innovative interference-sensitive mode selector may well be implemented in a cellular radiotelephone communication system, although the scope of the ivention is not limited in this regard. Types of cellular radiotelephone transmitters and/or receivers intended to be within the scope of the present invention may include, but are not limited to, Code Division Multiple Access (CDMA), CDMA-2000 and wideband CDMA (WCDMA) cellular radiotelephone receivers for receiving spread spectrum signals, Global System for Mobile communication (GSM) cellular radiotelephone, General Packet Radio Service (GPRS), Extended GPRS (EGPRS), third generation cellular systems (3G), and the like. For simplicity, although the scope of the invention is in no way limited in this respect, embodiments of the invention described below may be related to a CDMA family of cellular radiotelephone systems that may include CDMA, WCDMA, CDMA 2000 and the like.

Alternatively, embodiments of the invention may well be implemented in wireless data communication networks such as those defined by the Institute for Electrical and Electronics Engineers (IEEE). Technical detail regarding some of the operating characteristics of such devices may be found in, e.g., the IEEE 802.11, 1999 Edition; Information Technology Telecommunications and Information Exchange Between Systems—Local and Metropolitan Area Networks—Specific Requirements, Part 11: WLAN Medium Access Control (MAC) and Physical (PHY) Layer Specifications, its progeny and supplements thereto (e.g., 802.11a, .11b, .11g and .11n). See, also, the IEEE Std 802.16-2004 EEE Standard for Local and Metropolitan area networks Part 16: Air Interface for Fixed Broadband Wireless Access Systems, its progeny and supplements thereto (e.g., 802.16a, .16d, and .16e).

Example Communication System

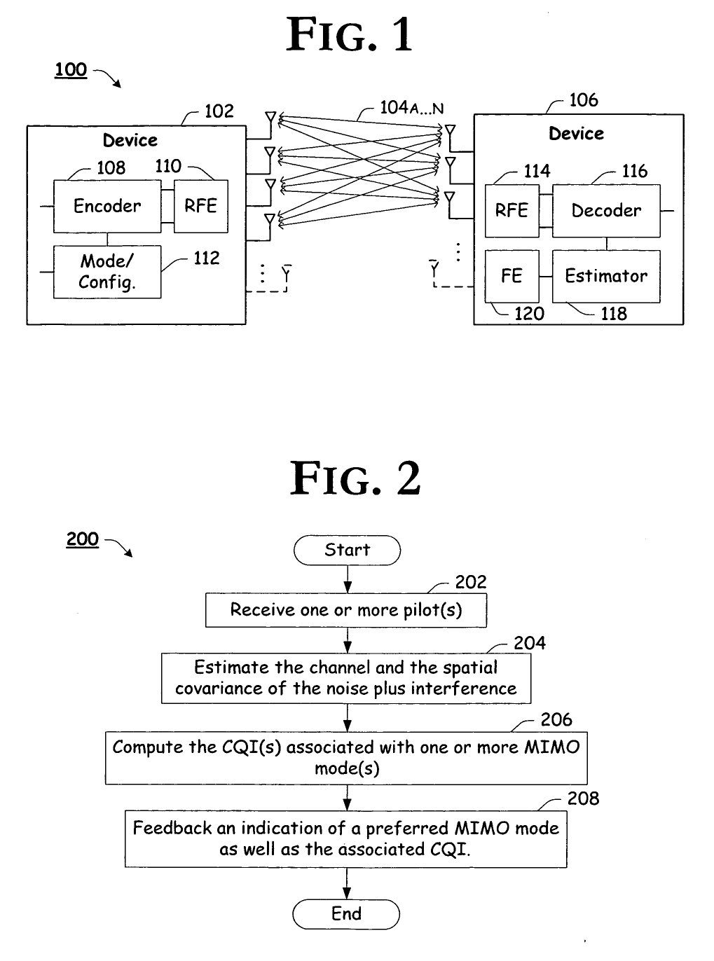

Turning to FIG. 1, a block diagram of an example wireless communication system 100 is depicted within which embodiments of the invention may well be practiced. In accordance with the illustrated example embodiment of FIG. 1, an example communications environment 100 is depicted comprising one wireless communications device 102 in communication with another wireless communications device 106 through a wireless communication link 104.

According to one embodiment, for purposes of illustration and not limitation, communication network 100 will be described in the context of a 3G cellular radiotelephone communication system. In such an example, device 102 may be referred to as a base transceiver station (BTS) (or, base station, access point, base, etc.), while device 106 may be referred to as user equipment (UE) (or, mobile station, station (STA), and the like), although the scope of the invention is not limited in this regard.

According to one example embodiment, device 102 is illustrated depicting a subset of an example transmitter architecture. More particularly, device 102 is depicted comprising one or more encoder(s) 108, radio frequency (RF) front end(s) (RFE) 110 and a mode controller/configurator 112, each generally coupled as depicted. According to one embodiment, encoder 108 is a MIMO encoder, wherein the encoder receives data content for transmission and encodes such data in accordance with one or more MIMO mode selections. According to one aspect, the MIMO mode selection is made by mode controller 112 in response to feedback received from a remote receiver (e.g., device 106). The encoded data content is provided to RFE 110 for upcoversion, amplification and transmission via one or more of the plurality of antenna(e), as shown.

According to one example embodiment, device 106 is illustrated depicting a subset of an example receiver architecture. More particularly, device 106 is depicted comprising one or more of a radio frequency (RF) front end (RFE) 114, a decoder 116, an estimator 118 and a feedback element 120, each generally coupled as depicted. As shown, a wireless communication channel is received via one or more of a plurality of antenna(e) and provided to the RFE 114, where it may be filtered, amplified, etc., before being applied to decoder 116. According to one embodiment, decoder 116 is a MIMO decoder. Decoder 116 decodes the content received via the communication channel and may provide it to one or more additional processing elements for additional signal and/or application processing.

According to one embodiment, decoder 116 may identify content (e.g., symbols) associated with pilot signals (or, tones, symbols, etc.) within the received commmunication channel. Such content may be routed to estimator 118. According to one embodiment described more fully below, estimator 118 may generate a channel estimate based, at least in part, on at least a subset of the pilot symbols to quantify one or more operational characteristics of the communication channel.

In addition, estimator 118 may generate an estimate of the spatial covariance of the noise plus interference from at least a subset of the pilot symbols. According to one embodiment, estimator 118 may generate an example channel estimate and full spatial covariance of the noise plus interference for each of a number of alternate MIMO channel modes from at least a subset of the pilot symbols. According to one embodiment, estimator 118 may be implemented within a digital signal processor, and may utilize an enhanced maximum-likelihood estimator that utilizes the turbo decoder a-posteriori log-likelihood ratios to smooth-out the effects of the unknown transmitted symbols, thus providing the log-likelihood sequence required for the covariance estimation, although the invention is not limited in this respect.

According to one embodiment, data associated with the channel estimate and the spatial covariance of the noise plus interference may be provided to the feedback element 120. In such an embodiment, the feedback element may compute a channel quality indicator (CQI) for each of the different MIMO channel modes from which a preferred MIMO mode is selected. Once selected, information denoting the preferred MIMO mode as well as the associated CQI is then provided back to the servicing transmitter (e.g., 102) and, more particularly, to a mode controller (e.g., 112) of the source transmitter.

Although depicted as a number of disparate functional blocks, those skilled in the art will appreciate that one or more elements of the transmitter (108-112) and/or the receiver (114-120) may well be combined into multi-functional block(s) without deviating from the spirit or scope of the claimed invention.

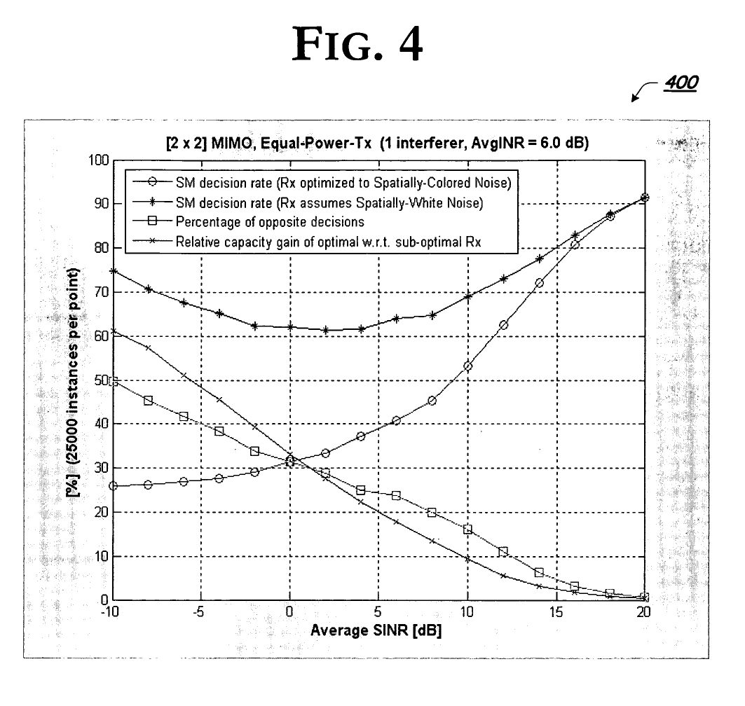

It will be appreciated that by providing information regarding both the channel estimate as well as full spatial covariance of noise plus interference, a much more accurate mode selection is effected wherein the transmitter is able to take into account not only the white-noise channel conditions, but also information regarding the interference perceived at the target receiver(s). It will be shown (see, e.g., FIG. 4) that such an implementation provides significant performance improvements while being computationally efficient and, as such, feasible from an implementation perspective.

Channel Model and Notation

The well-known (complex baseband) model describing a narrowband MIMO system (with N Tx antennas and M Rx antennas) may be represented as:
\vec{r}=H\vec{s}+\vec{n}, (1)
where \vec{r} is the Rx output array (column vector of size M), \vec{s} is the Tx input array (of size N), H is the M×N channel matrix, and \vec{n} is an additive “noise” array (of size M). The “noise” is composed of thermal noise generated at the receiver (assumed spatially-white AWGN with equal power σ₂ⁿ per array element), and an interference component whose spatial covariance is denoted (without loss of generality) as σ₂ⁿR. Using the assumption of no correlation between the thermal noise and the interference, the overall “noise” covariance may be represented as:
Λ:=E{\vec{n}\vec{n}′}=σₙ²(I+R), (2)
where ′ denotes the conjugate-transpose operation, I is the identity matrix (of size M×M in this case), and E{ } denotes taking the expectation value.

If the transmitter does not have any knowledge of the channel and interference conditions, one (perhaps optimal) transmission strategy is to equally split the total available power between all the antennas, leading to the following expression for the theoretical channel capacity:

$$C = {log}_{2} det ( I + \frac{P}{N} \tilde{H} {\tilde{H}}^{′} ) , \qquad ( 3 )$$

where the total noise-normalized transmitted power P is defined by:
P:=σₙ⁻²trP=σₙ⁻²trE{\vec{s}\vec{s}′}, (4)
and the “spatially-whitened channel matrix” is given by:
\tilde{H}:=Λ^{-1/2}H. (5)

If, alternatively, information about the channel and interference conditions (namely \tilde{H}) is available at the transmitter, a better transmission strategy can be found by “water-filling”, that is splitting the available power P between the Tx antennas so as to maximize the (theoretical) capacity, according to

$${C}^{′} = {sup}_{P ; tr P = P} {log}_{2} det ( I + \tilde{H} P {\tilde{H}}^{′} ) . \qquad ( 6 )$$

Thus, the (forward) link throughput can be increased, though at the cost of an extra feedback necessary for transferring Channel and Interference State Information (CISI) from the receiver to the transmitter. This leads to some tradeoff between the forward and backward link throughputs, and it is desirable to find some optimal compromise; namely, feeding back only partial CISI that captures the essence of the current conditions, and can be exploited by the transmitter to obtain most of the potential throughput gain in the forward link.

Several example alternatives for the content of the partial CISI feedback may include one or more of:
(a) In the case of a 2×2 MIMO system, a single-bit mode indicator specifying whether the current channel and interference conditions favor transmission with Spatial Multiplexing (SM) order of 2 (namely, simultaneously transmitting 2 independent streams of symbols from the 2 Tx antennas), or rather using SM order of 1 with Space-Time Transmit Diversity (STTD). According to one embodiment, the MIMO mode indicator is accompanied by a Channel Quality Indicator (CQI) feedback, based on which the transmitter may select an (e.g., optimal) Modulation and Coding Scheme (MCS).
(b) The rank of the matrix \tilde{H}, indicating to the transmitter the maximal SM order supported by the current conditions.
(c) An antenna (or beam) ordering or subset selection, indicating to the transmitter which Tx antennas (beams) out of the N are preferable under the current conditions.
(d) Direct Channel and Interference FeedBack (DCIFB), namely the full matrix \tilde{H}, quantized to some finite accuracy or approximated by some representative in a certain predefined “matrix codebook”.
(e) Precoding matrix \tilde{V}, namely the unitary matrix appearing in the Singular-Value Decomposition (SVD) \tilde{H}=Ũ\tilde{D}\tilde{V}′, suitably quantized or codebook-represented.
   Example Operation

Having introduced the intereference-sensitive MIMO mode selection in the context of an example transmitter and receiver architecture, above, a more detailed explanation of a number of embodiments are now provided, below. For ease of illustration, and not limitation, the following discussion of the different embodiments will be provided within the context of the communication system components of FIG. 1. It should be appreciated, however, that communication systems of greater or lesser complexity are anticipated within the scope and spirit of this disclosure.

Turning to FIG. 2, a flow chart of an example receiver operation is provided in more detail, according to but one example embodiment. In accordance with the illustrated example of FIG. 2, the method begins with block 202 wherein a receiver (106) receives one or more pilot(s) from a remote transmitter (102). At the onset, the transmitter is assumed to have very limited (or no) knowledge of the channel and covariance of the interference plus noise. Accordingly, the transmitter transmits with equal power from its antennas (e.g., 2), no matter which mode is being used (SM or STTD).

In block 204, the receiver estimates the channel and the spatial covariance of the interference plus noise. More particularly, according to one embodiment, the estimator 118 of the receiver generates a channel estimate and the full spatial covariance of the interference plus noise. In the SM mode of operation, we assume an Linear Minimum Mean Square Error (LMMSE) detection mechanism at the receiver, where each stream is regarded at the receiver as interference to the other stream. According to one embodiment, the estimator 118 may employ an enhanced maximum-likelihood estimator that utilizes the turbo decoder a-posteriori log-likelihood ratios to smooth-out the effects of the unknown transmitted symbols, thus providing the log-likelihood sequence required for the covariance estimation, although the invention is not limited in this respect. According to one embodiment, the MIMO-mode selection is based, at least in part, on a Signal to Interference plus Noise Ratio (SINR) criterion as computed at the receiver.

In block 206, the receiver computes the channel quality indicator(s) associated with one or more MIMO modes. According to one embodiment, the feedback element 120 may compute two SINR (or equivalently CQI) measures, one for the SM MIMO mode and the other for the STTD MIMO mode, and decides according to the associated capacities which mode is preferable. Using the notation above, the STTD measure \tilde{γ}_{STTD} and associated capacity \tilde{C}_{STTD} are given by:
\tilde{γ}_{STTD}=tr(\tilde{H}′\tilde{H}), \tilde{C}_{STTD}=log₂(1+\tilde{γ}_{STTD}), (7)
whereas the SM capacity is given by:

$${\tilde{C}}_{SM} = {\sum }_{i = 1}^{2} {log}_{2} ( 1 + {\tilde{γ}}_{SM , i} ) , \qquad ( 8 )$$

may be computed from the two per-stream SM measures:

$${\tilde{γ}}_{SM , i} = {{\vec{h}}_{i}^{′} ( {\vec{h}}_{j} {\vec{h}}_{j}^{′} + Λ )}^{- 1} {\overline{h}}_{i} = \frac{{\vert {\vec{\tilde{h}}}_{i} \vert}^{2} + det ( {\tilde{H}}^{′} \tilde{H} )}{{\vert {\vec{\tilde{h}}}_{j} \vert}^{2} + 1} , i , j = 1 , 2 , i \neq j , \qquad ( 9 )$$

where \vec{h}ᵢ (\vec{\tilde{h}}ᵢ) denotes the i-th column vector of the matrix H (\tilde{H}), respectively. The interference-aware decision criterion reads:

$$\begin{matrix}{\tilde{C}}_{SM} > {\tilde{C}}_{STTD} \\ {\tilde{C}}_{STTD} \geq {\tilde{C}}_{SM}\end{matrix} \} ⇒ Preferred MIMO mode is \{ \begin{matrix}SM \\ STTD .\end{matrix} \qquad ( 10 )$$

In block 208, the receiver may feed back to the transmitter an indication of a preferred MIMO mode as well as an associated CQI. According to one embodiment, the feedback element 120 may feedback a 1-bit indicator encoding this decision in addition to the “winning” CQI measure \tilde{C}ₘₐₓ=max(\tilde{C}_{SM}, \tilde{C}_{STTD}).

Based on such feedback the transmitter (102) may dynamically modify its MIMO mode for subsequent transmissions, providing the receiver (106) with an indication of the selected modulation and coding scheme (MCS) selected.

Performance Evaluation

In order to appreciate the gain of the interference-sensitive mode selection technique, generally introduced above, over the sub-optimal interference-indifferent procedure, an analysis of the latter is herein provided. In this regard, consider an alternative receiver which handles the same given scenario (the same received signal), but treats the interference plus noise as if it were spatially white (i.e., without consideration of the interference element). Thus, in the STTD mode of operation, such a receiver uses the pure-channel vectors \vec{h}ᵢ as combining weights for the signals received at the two antennas (rather than the optimal whitened vectors \tilde{\vec{h}}ᵢ used in the derivation of eqn. (7)), leading to the following modified measure and associated capacity:
γ_{STTD}=(tr(H′H))²/tr(\tilde{H}′\tilde{H}), C_{STTD}=log₂(1+γ_{STTD}). (11)

In the SM mode, on the other hand, the LMMSE detection procedure requires an estimate of the noise plus interference. Here the interference-indifferent receiver will use—instead of eqn. (2)—the wrong estimate:
E{\vec{n}\vec{n}′}≈\hat{Λ}=\hat{σ}ₙ²I, where \hat{σ}ₙ²=M⁻¹trΛ=σₙ²(1+M⁻¹tr R), (12)
and the resulting modified per-stream SINR measures and associated capacity are given by the following expressions:

$$\begin{matrix}{C}_{SM} = {\sum }_{i = 1}^{2} {log}_{2} ( 1 + {γ}_{SM , i} ) , and & ( 13 ) \\ {γ}_{SM , i} = \frac{{( {{\vec{h}}_{i}^{′} ( {\vec{h}}_{j} {\vec{h}}_{j}^{′} + \hat{Λ} )}^{- 1} {\vec{h}}_{i} )}^{2}}{{{\vec{h}}_{i}^{′} ( {\vec{h}}_{j} {\vec{h}}_{j}^{′} + \hat{Λ} )}^{- 1} ( {\vec{h}}_{j} {\vec{h}}_{j}^{′} + Λ ) {( {\vec{h}}_{j} {\vec{h}}_{j}^{′} + Λ )}^{- 1} {\vec{h}}_{i}} , \\ i , j = 1 , 2 , i \neq j . & ( 14 )\end{matrix}$$

Accordingly, the interference-indifferent decision criterion reads:

$$\begin{matrix}{C}_{SM} > {C}_{STTD} \\ {C}_{STTD} \geq {C}_{SM}\end{matrix} \} ⇒ Preferred MIMO mode is \{ \begin{matrix}SM \\ STTD ,\end{matrix} \qquad ( 15 )$$

and in addition to this modified MIMO-mode indicator the receiver feeds back to the transmitter the winning CQI measure Cₘₐₓ=max(C_{SM}, C_{STTD}).

Turning to FIG. 4, the effectiveness of the proposed intereference-sensitive mode selection is contrasted with that of more conventional techniques. As shown, the accuracy of selecting the “right” mode (i.e., that which provides the best capacity) in the the presence of a single dominant interfering signal whose power is 6 dB above the thermal noise (on average) is presented. The figure is based on a simulation in which the 2×2 channel matrix H and the 2×1 interferer channel matrix (dictating the covariance matrix R) were randomized at different values of the average SINR (25,000 instances per each average SINR point). Presented, as a function of the average SINR, are:
a) the percentage of instances in which the preferred MIMO mode was SM, based on the optimal criterion (10);
b) The percentage of instances in which the preferred MIMO mode was SM, based on the sub-optimal criterion (15);
c) The percentage of instances in which the preferred MIMO modes based on the criteria (10) and (15) differed; and
d) The relative gain in capacity achieved when using the optimal procedure, namely (\tilde{C}ₘₐₓ/Cₘₐₓ−1).
   Generalization to Point-to-Multipoint Systems

Although the foregoing was presented in the context of a point-to-point communications environment (e.g., 100), those skilled in the art will appreciate that it may be readily extendible to a point-to-multipoint system as well. In a point-to-multipoint communication system (e.g. the downlink (i.e., communication from the base station to remote subscriber(s)) in a single cell of a cellular system, where a single base-station transmits to many mobile terminals), further scheduling mechanisms may be deployed in an attempt to improve (i.e., substantially optimize) the resource allocation to different receivers.

In particular, due to the varying fading conditions experienced by different receivers competing over the same frequency resource(s), it is advantageous to schedule the transmission to each receiver at time intervals during which its reception conditions are favorable. The scheduling mechanism must rely then on the receivers' CQI feedback, and again, the improved quality of the novel interference-sensitive feedback proposed herein will enhance the overall system performance (e.g. total throughput) by allowing better scheduling decisions.

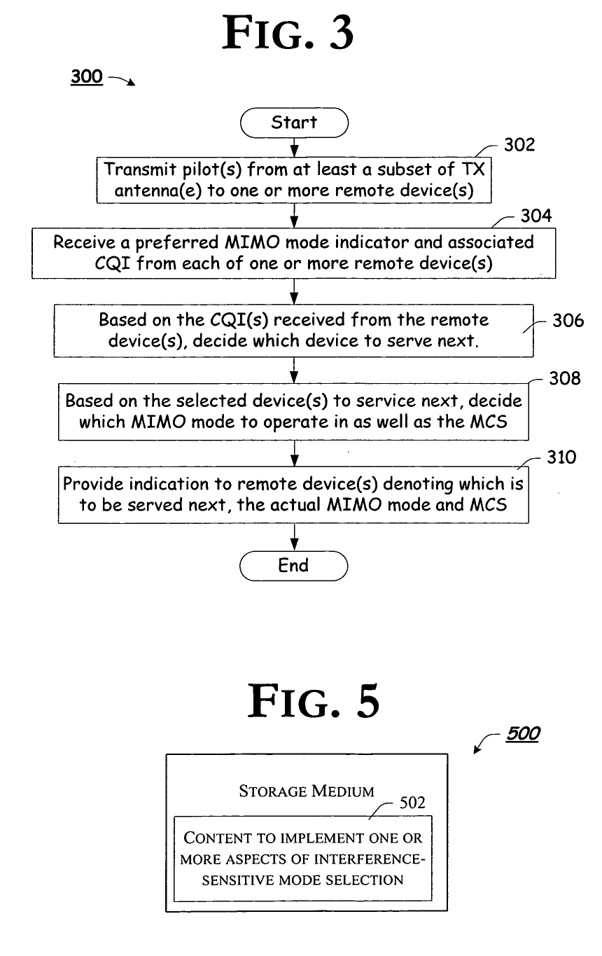

An example method extending the utilization of the interference-sensitive mode selection techniques introduced above are developed with reference to FIG. 3. Turning to FIG. 3, the process begins when a transmitter (e.g., 102) sends sends MIMO pilots (predefined symbol sequences, known to all receivers, from all Tx antennas), block 302.

As introduced above (see, e.g., FIG. 2), based on the received pilots, all the receivers estimate the channel and the full spatial covariance of the noise plus interference, and compute the resulting CQIs associated with the alternative MIMO modes. Each receiver transmits as feedback to the transmitter the preferred MIMO-mode indicator as well as the associated CQI. In block 304, the source transmitter receives this preferred MIMO mode indicator and associated CQI from each of the one or more remote receiver(s).

In block 306, based at least in part on the CQIs received from all receivers, the transmitter decides which receiver to serve next. According to one example embodiment, the mode selection element 112 decides which receiver to serve in the next time interval, e.g., using some decision algorithm (such as max-CQI, or some variations ensuring relative fairness of the shared resource allocation).

In block 308, for the selected receiver, the mode selection element 112 of the source transmitter selects the MIMO mode to operate in the subsequent transmission interval as well as the associated modulation and coding scheme, e.g., based on that receiver's feedback.

According to one embodiment, the transmitter may provide an indication to all receivers which one of them is going to be served next, and may indicate to the selected receiver the actual MIMO mode and MCS to be used, block 310, although the scope of the invention is not limited in this regard.

Generalization to Multicarrier-Based Systems

Further extensions to the underlying techniques to deployment within multicarrier based systems are also envisaged. In a broadband multicarrier-based communication system (e.g. OFDM), further generalizations of the invention are possible and in fact necessary for better exploiting its potential. Basically, the narrowband MIMO model, introduced above, would apply separately to each carrier (a.k.a. frequency bin). Depending on the channel's coherence bandwidth, the full bandwidth of the system can be divided into sub-bands, consisting of clusters (or chunks) of consecutive frequency bins along which the channel is relatively flat. In general, this situation can be described by the following set of parameters:

N_{b}=total number of frequency bins;

N_{c}=number of frequency chunks (or sub-bands);

bₖ=number of frequency bins in the k-th chunk (k=1, 2, . . . , N_{c},), satisfying

$${\sum }_{k = 1}^{{N}_{c}} {b}_{k} = {N}_{b} .$$

Hₖ=the M×N channel matrix in the k-th chunk.

The frequency chunks may then be treated, for purposes herein, as independent frequency resources, and in particular deploy different MIMO modes as well as different MCSs in each of them. The only subtlety in the extension from the general case detailed above involves the estimation/computation of the covariance matrix Λₖ associated with chunks that contain more than a single bin (i.e. bₖ>1), given that we know how to compute the covariance per bin. One can in general perform various (weighted) averaging procedures, including as special degenerate options such as, e.g., the following:

Take Λₖ as Λ of the bin at the center of the chunk.

Take Λₖ as Λ of the bin at in the chunk for which the channel estimator is most reliable.

Take Λₖ as the average of the Λ s of all the bins in the chunk.

Once this is done, one can follow the process detailed above, e.g., as a particular example in the 2×2 MIMO configuration, for each chunk and the procedure defined in FIG. 2 can then be generalized to the multicarrier-based case as follows:
a) The transmitter sends MIMO pilots (predefined symbol sequences, known to the receiver, from all Tx antennas).
b) Based on the received pilots, the receiver estimates for each chunk of bins the channel and the full spatial covariance of the noise plus interference, and computes the resulting CQIs associated with the alternative MIMO modes per chunk.
c) The receiver transmits as feedback to the transmitter the preferred MIMO-mode indicators as well as the associated CQIs, per chunk.
d) Based on the received feedback, the transmitter selects the MIMO mode to operate with per chunk in subsequent transmissions as well as the associated MCS.
e) The transmitter indicates to the receiver the actual MIMO modes and MCSs (selected in (d)) per chunk.
   Generalization to Multiple Access (MA) Multicarrier-Based Systems

Further combinations of the teachings above are anticipated to cover multiple access, multicarrier based systems, e.g., a broadband multicarrier-based communication system in which shared frequency resources are allocated to different receivers at different times (e.g. OFDMA). That is, the concepts detailed above may well be combined to support a multiple access, multicarrier-based communication system.

Example Estimator

According to one aspect of an embodiment of the invention, a receiver 106 implements a novel estimator (118). More particularly, a digital signal processor in the receiver may implement a novel estimation algorithm of the interference-plus-noise covariance. Within the framework and parameters introduced above, the task is to estimate the following M×M matrix:
Λ:=E{\vec{n}\vec{n}′}=E{(\vec{r}−H\vec{s})(\vec{r}−H\vec{s})′} (16)
based on a finite number of observation vectors \vec{r}ₜ, t=1, 2, . . . , Lₙ, received within a certain time interval of length Lₙ during which the channel H is assumed not to change significantly. Given the estimated channel matrix Ĥ and the set of transmitted symbols \vec{s}ₜ (either known pilots, or symbols which were decoded by the receiver accompanied by a measure of their decoding reliability), the matrix in (16) can be estimated as the following weighted average:

$$\hat{Λ} = {\sum }_{t = 1}^{{L}_{n}} {ω}_{t} ( {\vec{r}}_{t} - \hat{H} {\vec{s}}_{t} ) {( {\vec{r}}_{t} - \hat{H} {\vec{s}}_{t} )}^{′} , where {ω}_{t} \geq 0 , {\sum }_{t = 1}^{{L}_{n}} {ω}_{t} = 1. \qquad ( 17 )$$

The “weights” ωₜ reflect the reliability measure of the t-th observation and/or its relevance for the current estimation (namely, the weights assigned to observations which are farther in the past can be smaller than those assigned to “fresh” observations). Generalizations of the above estimation procedure to the multicarrier case can be implemented as outlined in section above.

### Alternate Embodiment(s)

FIG. 5 illustrates a block diagram of an example storage medium comprising content which, when invoked, may cause an accessing machine to implement one or more aspects of the interference-sensitive mode selection architectures, techniques, protocols and interface signals described hereinabove. In this regard, storage medium 500 may include content 502 (e.g., instructions, data, or any combination thereof) which, when executed, causes an accessing appliance to implement one or more aspects of one or more of an estimator (118), a feedback element (120), and/or a mode selection element 112 generally introduced above.

The machine-readable (storage) medium 500 may include, but is not limited to, floppy diskettes, optical disks, CD-ROMs, and magneto-optical disks, ROMs, RAMs, EPROMs, EEPROMs, magnet or optical cards, flash memory, or other type of media/machine-readable medium suitable for storing electronic instructions. Moreover, the present invention may also be downloaded as a computer program product, wherein the program may be transferred from a remote computer to a requesting computer by way of data signals embodied in a carrier wave or other propagation medium via a communication link (e.g., a modem, radio or network connection). As used herein, all of such media is broadly considered storage media.

Embodiments of the present invention may also be included in integrated circuit blocks referred to as core memory, cache memory, or other types of memory that store electronic instructions to be executed by the microprocessor or store data that may be used in arithmetic operations.

Embodiments of the invention may include various operations. Such operations may be performed by hardware components, or may be embodied in machine-executable content (e.g., firmware and/or software instructions), which may be used to cause a general-purpose or special-purpose processor or logic circuits programmed with the instructions to perform the operations. Alternatively, the operations may be performed by a combination of hardware and software. Moreover, although the invention has been described in the context of a computing appliance, those skilled in the art will appreciate that such functionality may well be embodied in any of number of alternate embodiments such as, for example, integrated within a communication appliance (e.g., a cellular telephone).

In the description above, for the purposes of explanation, numerous specific details are set forth in order to provide a thorough understanding of the present invention. It will be apparent, however, to one skilled in the art that the present invention may be practiced without some of these specific details. In other instances, well-known structures and devices are shown in block diagram form. Any number of variations of the inventive concept are anticipated within the scope and spirit of the present invention. In this regard, the particular illustrated example embodiments are not provided to limit the invention but merely to illustrate it. Thus, the scope of the present invention is not to be determined by the specific examples provided above but only by the plain language of the following claims.

What is claimed is:

1. A method comprising:
receiving pilot tone(s) from a remote transmitter;
generating an estimate of the channel and the spatial covariance of the noise plus interference from at least a subset of the received pilot tone(s); and
computing channel quality indicator(s) (CQI) associated with each of at least a subset of a plurality of MIMO modes based, at least in part, on the generated estimate of the channel and the spatial covariance of the noise plus interference, from which a selection of a preferred MIMO mode is made.

2. A method according to claim 1, further comprising:
selecting a preferred MIMO mode; and
feeding back an indication of the selected preferred MIMO mode and an associated CQI to a remote transmitter.

3. A method according to claim 1, wherein the plurality of MIMO modes include a spatial multiplexing (SM) mode and a space-time transmit diversity (STTD) mode.

4. A method according to claim 1, the estimation step comprising:
employing an enhanced maximum-likelihood estimator that utilizes a turbo decoder a-posteriori log-likelihood ratios to smooth-out the effects of any unknown transmitted symbols to provide the log-likelihood sequence required for covariance estimation.

5. A method according to claim 1, the CQI comprising a measure of Signal to Interference plus Noise Ratio (SINR).

6. A method according to claim 1, further comprising:
selecting a preferred MIMO mode from a plurality of MIMO modes including a spatial multiplexing mode and a space-time transmit diversity mode based, at least in part, on which would provide a higher throughput capacity.

7. A method according to claim 6, wherein the STTD measure \tilde{γ}_{STTD} and associated capacity \tilde{C}_{STTD} are given by:
\tilde{γ}_{STTD}=tr(\tilde{H}′\tilde{H}), \tilde{C}_{STTD}=log₂(1+\tilde{γ}_{STTD}),
and the SM capacity is given by:
$${\tilde{C}}_{SM} = {\sum }_{i = 1}^{2} {log}_{2} ( 1 + {\tilde{γ}}_{SM , i} ) ,$$
which may be computed from the two per-stream SM measures:
$${\tilde{γ}}_{SM , i} = {{\vec{h}}_{i}^{′} ( {\vec{h}}_{j} {\vec{h}}_{j}^{′} + Λ )}^{- 1} {\vec{h}}_{i} = \frac{{\vert {\vec{\tilde{h}}}_{i} \vert}^{2} + det ( {\tilde{H}}^{′} \tilde{H} )}{{\vert {\vec{\tilde{h}}}_{j} \vert}^{2} + 1} , i , j = 1 , 2 , i \neq j ,$$
where \vec{h}ᵢ (\tilde{\vec{h}}ᵢ) denotes the i-th column vector of the matrix H (\tilde{H}), respectively.

8. A method according to claim 7, wherein a decision criterion for selection of a preferred MIMO mode may be represented as:
$$\begin{matrix}{\tilde{C}}_{SM} > {\tilde{C}}_{STTD} \\ {\tilde{C}}_{STTD} \geq {\tilde{C}}_{SM}\end{matrix} \} ⇒ Preferred MIMO mode is \{ \begin{matrix}SM \\ STTD .\end{matrix}$$

9. A method according to claim 8, further comprising:
feeding back to a remote transmiter an indicator of the selected preferred MIMO mode, wherein the feedback is a 1-bit indicator encoding this decision in addition to the “winning” CQI measure \tilde{C}ₘₐₓ=max(\tilde{C}_{SM},\tilde{C}_{STTD}).

10. An apparatus comprising:
a receiver, responsive to one or more pilot(s), to generate an estimate of the channel and the spatial covariance of the noise plus interference from at least a subset of the received pilot tone(s), and to compute channel quality indicator(s) (CQI) associated with each of at least a subset of a plurality of MIMO modes based, at least in part, on the generated estimate of the channel and the spatial covariance of the noise plus interference, from which a selection of a preferred MIMO mode is made.

11. An apparatus according to claim 10, the receiver comprising:
an estimator, to generate the estimate of the channel and the full spatial covariance of the noise plus interference.

12. An apparatus according claim 11, wherein the estimator utilizes an enhanced maximum-likelihood estimator that utilizes a turbo decoder a-posteriori log-likelihood ratios to smooth-out the effects of any unknown transmitted symbols to provide the log-likelihood sequence required for covariance estimation.

13. An apparatus according to claim 10, the receiver comprising:
a feedback element, responsive to the generated estimate of the channel and the spatial covariance of the noise plus interference, to select a preferred MIMO mode based, at least in part on the computed CQIs, and to feed back an indication of the selected preferred MIMO mode and an associated CQI to a remote transmitter.

14. An apparatus according to claim 13, the CQI comprising a measure of a Signal to Interference plus Noise Ratio (SINR) perceived at the receiver.

15. An apparatus according to claim 13, wherein the feedback element selects the preferred MIMO mode from a plurality of MIMO modes including a spatial multiplexing mode and a space-time transmit diversity mode based, at least in part, on which would provide a higher throughput capacity.

16. An apparatus according to claim 15, wherein the STTD measure \tilde{γ}_{STTD} and associated capacity \tilde{C}_{STTD} are given by:
\tilde{γ}_{STTD}=tr(\tilde{H}′\tilde{H}), \tilde{C}_{STTD}=log₂(1+\tilde{γ}_{STTD}),
and the SM capacity is given by:
$${C}_{SM} = {\sum }_{i = 1}^{2} {log}_{2} ( 1 + {γ}_{SM , i} ) ,$$
which may be computed from the two per-stream SM measures:
$${\tilde{γ}}_{SM , i} = {{\vec{h}}_{i}^{′} ( {\vec{h}}_{j} {\vec{h}}_{j}^{′} + Λ )}^{- 1} {{h}^{->}}_{i} = \frac{{\vert {\vec{\tilde{h}}}_{i} \vert}^{2} + det ( {\tilde{H}}^{′} \tilde{H} )}{{\vert {\vec{\tilde{h}}}_{j} \vert}^{2} + 1} , i , j = 1 , 2 , i \neq j ,$$
where \vec{h}ᵢ (\tilde{\vec{h}}ᵢ) denotes the i-th column vector of the matrix H (\tilde{H}), respectively.

17. An apparatus according to claim 16, wherein a decision criterion for selection of a preferred MIMO mode by the feedback element may be represented as:
$$\begin{matrix}{\tilde{C}}_{SM} > {\tilde{C}}_{STTD} \\ {\tilde{C}}_{STTD} \geq {\tilde{C}}_{SM}\end{matrix} \} ⇒ Preferred MIMO mode is \{ \begin{matrix}SM \\ STTD .\end{matrix}$$

18. An apparatus according to claim 17, wherein the feedback element feeds back to a remote transmiter an indicator of the selected preferred MIMO mode, wherein the feedback is a 1-bit indicator encoding this decision in addition to the “winning” CQI measure \tilde{C}ₘₐₓ=max(\tilde{C}_{SM},\tilde{C}_{STTD}).

19. A system comprising:
a plurality of antennae through which a communication channel may be established with a remote device; and
a receiver, responsive to one or more pilot(s) received via at least a subset of the plurality of the antennae, to generate an estimate of the channel and the spatial covariance of the noise plus interference from at least a subset of the received pilot tone(s), and to compute channel quality indicator(s) (CQI) associated with each of at least a subset of a plurality of MIMO modes based, at least in part, on the generated estimate of the channel and the spatial covariance of the noise plus interference, from which a selection of a preferred MIMO mode is made.

20. A propogated signal, comprising feedback information representing a selected preferred MIMO mode and an associated CQI made by a receiver and directed to a source transmitter, the feedback information comprising an encoded n-bit indicator encoding the decision in addition to the “winning” CQI measure \tilde{C}ₘₐₓ=max(\tilde{C}_{SM},\tilde{C}_{STTD}).
